(19) United States
(12) Patent Application Publication
(10) Pub. No.: US 2014/0273513 A1
(43) Pub. Date: Sep. 18, 2014

(54) RESIST COMPOSITION AND MANUFACTURING METHOD OF SEMICONDUCTOR DEVICE

(71) Applicant: Sony Corporation, Tokyo (JP)

(72) Inventors: Isao Mita, Kumamoto (JP); Nobuyuki Matsuzawa, Tokyo (JP); Koji Arimitsu, Tokyo (JP)

(73) Assignee: Sony Corporation, Tokyo (JP)

(21) Appl. No.: 14/203,775

(22) Filed: Mar. 11, 2014

(30) Foreign Application Priority Data
Mar. 18, 2013 (JP) 2013-054934

(51) Int. Cl. G03F 7/16; H01L 21/027

(52) U.S. Cl. CPC G03F 7/168; H01L 21/0271
USPC 438/763; 524/27

(57) ABSTRACT

There is provided a resist composition including a crosslinking material configured to cause crosslinking in the presence of an acid, an inclusion compound, and a solvent.

### CROSS REFERENCE TO RELATED APPLICATIONS

This application claims the benefit of Japanese Priority Patent Application JP 2013-054934 filed Mar. 18, 2013, the entire contents of which are incorporated herein by reference.

### BACKGROUND

The present technology relates to a resist composition that reduces a size of an opening of a resist pattern when the pattern is formed in a manufacturing process of a semiconductor element and a manufacturing method of a semiconductor device using the resist composition.

In recent years, as semiconductor elements have become highly integrated, a size of a pattern which is necessary for a manufacturing process has become extremely miniaturized. In general, a fine pattern or fine impurity distribution is produced by forming a resist pattern with a photolithography technology and using the formed resist pattern as a mask. A fine pattern is produced on a base by etching various kinds of thin films of the base using, for example, the formed resist pattern as a mask. In addition, such fine impurity distribution is produced by performing ion-implantation in the base using the formed resist pattern as a mask.

The photolithography technology is very important in the formation of a fine pattern as described above. The photolithography technology includes processes of coating, exposure, and development of a resist. Miniaturization using this technology can be performed by mainly shifting an exposure wavelength to a short wavelength. However, shift to a short wavelength has a technical limitation and increases manufacturing costs, and thus there is a limitation of the technology of a wavelength shift.

For this reason, a formation method of a fine resist pattern that overcomes such a limitation of the photolithography technology using exposure in the related art has been proposed (for example, JP 2000-298356A). In the formation method of a resist pattern, the resist pattern is further miniaturized by performing an additional process on the resist pattern produced using the photolithography technology.

In the method described above, first a resist composition that includes a crosslinking material that causes crosslinking in the presence of an acid is coated on a resist pattern produced using the photolithography technology. Then, the acid present on the surface of the resist pattern causes a crosslinking reaction with the crosslinking material. Accordingly, a crosslinked layer is formed on the resist pattern produced in the photolithography technology, and thus the resist pattern can be further miniaturized.

### SUMMARY

However, in the method described above, the supply of the acid from the resist pattern produced in the photolithography technology causes the crosslinking reaction. For this reason, when incorporation of the acid from the resist pattern into the resist composition is not sufficient, the crosslinked layer is not satisfactorily formed, and the degree of miniaturization of an opening is insufficient.

As described above, such a miniaturization method of the related art in which a crosslinked layer is formed with a resist composition using supply of an acid from a resist pattern is faced with a problem in that it is difficult to achieve satisfactory miniaturization.

It is desirable to provide a resist composition and a manufacturing method of a semiconductor device that enable miniaturization of an opening of a resist pattern in the present technology.

A resist composition according to an embodiment of the present technology includes a crosslinking material configured to cause crosslinking in the presence of an acid, an inclusion compound, and a solvent.

In addition, a method for manufacturing a semiconductor device according to an embodiment of the present technology has a step of forming, on a semiconductor substrate, a first resist pattern configured to be able to supply an acid using a first resist composition. In addition, the method has a step of forming, on the first resist pattern, a second resist layer by coating a second resist composition configured to include a crosslinking material configured to cause crosslinking in the presence of an acid, an inclusion compound, and a solvent. Furthermore, the method has a step of forming a crosslinked layer in the second resist layer by diffusing the acid from the first resist pattern into the second resist layer, and a step of removing a non-crosslinked portion of the second resist layer.

In the resist composition according to an embodiment of the present technology, the acid generated in the resist pattern is included in the inclusion compound. For this reason, due to the presence of the inclusion compound, incorporation of the acid into the resist composition is promoted, and an amount of the acid sufficient for crosslinking of the crosslinking material is introduced into the resist composition. Thus, in a miniaturization method using formation of a crosslinked layer by supply of the acid, an even finer opening pattern can be formed.

Therefore, by using such a resist composition, a semiconductor device using a fine opening pattern can be manufactured.

According to an embodiment of the present technology, it is possible to provide a resist composition and a manufacturing method of a semiconductor device that enable miniaturization of an opening of a resist pattern.

### BRIEF DESCRIPTION OF THE DRAWINGS

FIGS. 1A to 1C are process diagrams for describing an embodiment of a method for manufacturing a semiconductor device of the present technology;

FIGS. 2D to 2F are process diagrams for describing an embodiment of a method for manufacturing the semiconductor device of the present technology; and

FIGS. 3A to 3C are SEM photographs of samples of resist patterns of an example and a comparative example.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, exemplary embodiments for implementing the present technology will be described, however, the present technology is not limited to the following examples.

Note that description will be provided in the following order.

1. Embodiment of a resist composition

2. Embodiment of a manufacturing method of a semiconductor device

3. Example of a manufacturing method of a semiconductor device

### <1. Embodiment of a Resist Composition>

Hereinafter, a detailed embodiment of a resist composition will be described.

A resist composition forms a new resist pattern in a portion that comes into contact with a side wall of a resist pattern that is produced through the photolithography technology using exposure. Hereinbelow, the resist composition will be described as a chemical shrink material and the resist pattern produced in the photolithography technology using exposure or the like as a first resist pattern. In addition, the new resist pattern formed by the resist composition (chemical shrink material) will be described as a second resist pattern.

The chemical shrink material is composed of an inclusion compound that can include an acid supplied from the first resist pattern in a portion thereof that comes into contact with a side wall of the first resist pattern, a crosslinking material that causes crosslinking in the presence of the acid, and a solvent.

Hereinafter, the composition of the chemical shrink material will be described in order of the solvent, the inclusion compound, and the crosslinking material.

[Solvent]

It is desirable for the chemical shrink material that forms a second resist layer not to exert influence on the first resist pattern when the material is coated. The influence mentioned here is, for example, a change in a shape, a property, or the like of a first resist layer, such as melting or swelling of the first resist pattern.

For this reason, the chemical shrink material is coated using a solvent that does not cause melting or the like of the first resist pattern. As such a solvent, for example, water, a water-soluble organic solvent that does not exert influence on the first resist pattern, a mixed solvent of water and a water-soluble organic solvent, or one or a mixture of organic solvents is used.

As the water-soluble organic solvent, for example, alcohols such as ethanol, methanol, or isopropyl alcohol, γ-butyrolactone, acetone, N-methylpyrrolidone, or the like can be used. The materials are mixed in a range not causing the first resist pattern to be melted in accordance with a melting property of a material that is used as a second resist composition.

In addition, as an organic solvent that does not exert influence on the first resist pattern, for example, one or a mixture of alcohol-based solvents or ether-based solvents such as ethanol, methanol, isopropyl alcohol, or dimethyl ether can be used.

[Inclusion Compound]

For the inclusion compound included in the chemical shrink material, a compound that can include the acid supplied from the first resist pattern in the portion that comes into contact with the side wall of the first resist pattern described above is used. The acid generated in the first resist pattern has a hydrophobic part in its partial structure. For this reason, as the chemical shrink material includes the inclusion compound that can include the acid having the hydrophobic part, it is possible to prompt diffusion of the acid present on the side wall of the first resist pattern into the chemical shrink material.

It is necessary for the inclusion compound included in the chemical shrink material to be able to be dissolved in a solvent such as water, the water-soluble organic solvent, or the organic solvent described above. As an inclusion compound that can be dissolved in such a solvent, for example, a cyclodextrin expressed by the following general formula (1) is exemplified.

[chemical structure]

The general formula (1) shows a structure of methyl-β-cyclodextrin as an example of a cyclodextrin. The cyclodextrin is one kind of cyclic oligosaccharide that has a ring structure formed by a few molecules of D-glucose bound to each other through an α(1→4) glucosidic bond. For example, a cyclic bond of six glucose units is called α-cyclodextrin, a cyclic bond of seven glucose units is called β-cyclodextrin, and a cyclic bond of eight glucose units is called γ-cyclodextrin.

The inside of a cyclodextrin is hydrophobic and the outside thereof is hydrophilic. For this reason, a cyclodextrin itself is soluble in water. In addition, a cyclodextrin has a characteristic of having a water-soluble property by incorporating a hydrophobic compound that is dissolved only in an organic solvent into the ring.

[Crosslinking Material]

As the crosslinking material included in the chemical shrink material, one or two or more kinds of crosslinking resins, one or two or more kinds of crosslinking agents, or a mixture thereof are used. Particularly, when water or a mixed solvent of water and a water-soluble organic solvent is used as a solvent, a water-soluble resin and a water-soluble crosslinking agent is preferably used.

As a crosslinking resin, for example, one or a mixture of a polyvinyl acetal resin, a polyvinyl alcohol resin, a polyacrylic resin, an oxazoline-containing water-soluble resin, an aqueous urethane resin, a polyallylamine resin, a polyethylenimine resin, a polyvinylamine resin, a water-soluble phenol resin, a water-soluble epoxy resin, a styrene-maleic copolymer, and the like can be used. In addition, as a crosslinking agent, for example, one or a mixture of a melamine-based crosslinking agent such as methylol melamine or methoxy methylol melamine, a urea-based crosslinking agent such as methoxy methylol urea or ethylene urea, an amino-based crosslinking agent such as isocyanate, benzoguanamine, or glycoluril, and the like can be used.

In addition, in addition to the compounds described above, a water-soluble polyol or water-soluble epoxy monomer described below can be used as a crosslinking material.

[chemical structure]

Note that the crosslinking material is not limited to the resin and crosslinking agent, and a crosslinking agent that is soluble in a solvent to be used and causes crosslinking with an acid and a resin that has a crosslinking group can be used. Particularly, when an aqueous solvent is used, any material may be used as long as the material is a water-soluble crosslinking agent that is soluble in the aqueous solvent and causes crosslinking with an acid and a water-soluble resin that has a crosslinking group that causes crosslinking with an acid.

In addition, when a mixture is used as a crosslinking material, an optimum composition may be set using the first resist composition to be applied, a set reaction condition, or the like.

### <2. Embodiment of a Manufacturing Method of a Semiconductor Device>

Hereinafter, a detailed embodiment of a manufacturing method of a semiconductor device will be described.

FIGS. 1A to 1C show process diagrams of the manufacturing method of a semiconductor device using the resist composition described above. FIGS. 1A to 1C are cross-sectional diagrams of a structure formed on a substrate. Note that, in the example below, an application of the embodiment to a positive resist will be described, however, the embodiment can also be applied to a negative resist.

[Manufacturing Method of a Semiconductor Device: First Step]

First, as shown in FIG. 1A, a first resist layer 12 composed of a first resist composition is formed on a semiconductor substrate 11. In the formation of the first resist layer 12, for example, spin coating or the like is used. After the first resist composition is spin-coated on the semiconductor substrate 11, the substrate is heated at a temperature of about 70° C. to 120° C. for about one minute to evaporate a solvent, and thereby the first resist layer 12 is formed. A thickness of the first resist layer 12 is, for example, about 0.04 μm to 5 μm.

Next, in order to form a pattern using the first resist composition, the first resist layer 12 is irradiated with an active energy ray via a photomask that has a shape to be transferred (hereinafter, this process will be referred to as “exposure”). As the active energy ray, for example, a g-ray, an i-ray, KrF (krypton fluoride) laser light, ArF (argon fluoride) laser light, F₂ laser light, EUV (extreme ultraviolet) light, an X-ray, an electron ray, or the like is used. Note that, when an electron ray is used, the first resist layer 12 is scanned using the electron ray without the photomask.

The structure and composition of the first resist composition are not particularly limited, and any structure and composition may be possible as long as the first resist composition contains a component that generates an acid from the irradiation of the active energy ray. Alternatively, a first resist composition that already contains an acid can also be used.

As a specific example, for example, a resist composition in which a novolac resin, a polyhydroxystyrene resin, an acrylic resin, or the like that has a protective group contains an onium salt-based photo-acid-generating agent or the like is exemplified. Note that a basic compound for neutralizing a part of a generated acid may also be included if necessary. In addition, as an acid that is included in the first resist composition in advance, an organic acid having a low molecular weight such as a carboxylic acid is preferable. This composition is a composition of a general chemically amplified resist, but is not limited thereto.

After performing exposure, a heating process that is called a PEB (Post-Exposure-Bake) process is performed on the first resist layer 12 if necessary. A temperature of the heating process is, for example, about 60° C. to 145° C. and a duration thereof is about 1 minute. Due to this process, sensitivity and resolution characteristics of the resist are enhanced.

Next, development is performed using, for example, an aqueous solution of TMAH (tetramethylammonium hydroxide) (with a concentration of 0.01 to 4 mass %) to remove the irradiated portion of the first resist layer 12 with the active energy ray. In this manner, a predetermined first resist pattern 13 is formed as shown in FIG. 1B.

Note that, after the development, an exposure process may be performed again on a part of or the entire resist pattern in order to generate more acid in the first resist pattern 13 if necessary. In addition, the heating process may be performed again after the exposure process.

In the case of a general chemically amplified resist, an acid derived from a photo-acid-generating agent is generated in the exposed portion. Then, due to a catalytic reaction of the generated acid, a protective group in a resin that is a main component of the first resist layer is deprotected, and thereby an organic acid such as a carboxylic acid is generated. The portion in which the organic acid is generated is easily melted by an alkaline developer such as an aqueous solution of TMAH (tetramethylammonium hydroxide) or the like. For this reason, the exposed portion is melted by the developer and then residual portions form the resist pattern.

In addition, in side wall portions of the first resist pattern 13, a trace amount of acid is generated from irradiation with light having given intensity. Furthermore, the trace amount of acid deprotects the resin component of the side wall portions as well, however, because the degree of deprotection is not sufficient, the portions are not melted by the alkaline developer, but remain as the first resist pattern 13.

Thus, when the first resist composition is a general chemically amplified resist, the acid is unevenly present on the side walls of the first resist pattern 13 as shown in FIG. 1B. Note that, in the drawing, the acid unevenly present on the side walls of the first resist pattern 13 is indicated as hydrogen ions (H⁺).

[Manufacturing Process of a Semiconductor Device: Second Step]

Next, as shown in FIG. 1C, a second resist composition is coated using spin coating or the like over the first resist pattern 13 to form a second resist layer 14. Hereinafter, the second resist composition is called a chemical shrink material when necessary. After the coating of the chemical shrink material, a heating process may be performed at a temperature of 80° C. to 105° C. for about one minute to evaporate the solvent if necessary.

After the second resist layer 14 is formed by coating the chemical shrink material, a heating process for diffusing the acid contained in the first resist pattern into the second resist layer 14 is performed (this process is called a mixing baking process). Conditions of the mixing baking process are, for example, a temperature of 70° C. to 150° C. and a duration of about one to two minutes. In addition, 120° C. or lower is preferable.

Through the mixing baking process, the acid in the first resist pattern 13 is diffused into the layer composed of the chemical shrink material as shown in FIG. 2D.

The acid generated from a photo-acid-generating agent (PAG) of the first resist pattern 13 has a hydrophobic part in a part of its structure. For this reason, the hydrophobic part of the acid is included in an inclusion compound contained in the chemical shrink material. Accordingly, the acid from the first resist pattern 13 is easily diffused into the second resist layer 14 as shown in FIG. 2E. Thus, because the chemical shrink material contains the inclusion compound, the supply of the acid from the first resist pattern 13 to the chemical shrink material is prompted.

The chemical shrink material includes a crosslinking material that causes crosslinking in the presence of an acid. For this reason, the crosslinking material causes a crosslinking reaction with the acid from the first resist pattern 13 described above in the second resist layer 14 that is a coating layer of the chemical shrink material.

In addition, a plurality of OH groups are present in the inclusion compound described above included in the chemical shrink material. For this reason, a dehydration and condensation reaction using an acid catalyst occurs by the inclusion compound and the crosslinking material as shown in the following formula (2).

[chemical structure]

In formula (2) above, a dehydration and condensation reaction occurs between OH groups of the cyclodextrin (CD) and the crosslinking material having OH groups in the presence of the acid catalyst (H⁺). Accordingly, the cyclodextrin (CD) and the crosslinking material are incorporated into a crosslinked structure.

In this manner, because the inclusion compound has the plurality of OH groups, the inclusion compound and the crosslinking material form the crosslinked structure.

Thus, as a crosslinking reaction between the crosslinking materials and the dehydration and condensation reaction between the crosslinking material and the inclusion compound occur, a crosslinked layer composed of the crosslinking materials and the inclusion compound is formed in the second resist layer 14. This crosslinked layer is formed in a portion that comes into contact with side walls of the first resist pattern 13 from which the acid is supplied. In addition, the portions in which the crosslinked layer is formed are insoluble in various solvents.

Next, washing is performed using a solvent that does not melt the first resist pattern 13. By washing with the solvent, a non-crosslinked portion of the second resist layer 14 is melted and removed.

Washing is performed using water or a mixed solvent of water and a water-soluble organic solvent, or an organic solvent as a solvent that does not melt the first resist pattern 13. For example, washing is performed using a mixed solvent in which water is mixed with isopropanol having a concentration in the range of about 1 to 30 mass %. In this manner, by melting the non-crosslinked portion of the second resist layer 14, a second resist pattern 15 that is formed of the crosslinked layer of the chemical shrink material and narrows openings of the first resist pattern 13 can be obtained.

Through the steps described above, the crosslinked layer is formed of the crosslinking material and the inclusion compound and the second resist pattern 15 that narrows the openings of the first resist pattern 13 is obtained. Furthermore, by repeating the steps from FIG. 1C to FIG. 2F described above when necessary, another crosslinked layer of a chemical shrink material and another resist pattern that narrows the openings can be formed.

Furthermore, using the first resist pattern 13 and the second resist pattern 15 which are formed in the steps from FIG. 1A to FIG. 2F described above as a mask, a semiconductor device can be manufactured using a method of the related art. The semiconductor device can be manufactured by performing, for example, etching on a base layer using the resist patterns as a mask, ion implantation using the patterns as a mask, and the like.

In the manufacturing method of a semiconductor device according to the present embodiment described above, since the second resist layer includes the inclusion compound, a sufficient amount of acid can be supplied from the first resist pattern to the second resist layer. For this reason, different from a pattern miniaturization method of the related art that uses a chemical shrink material to which a small amount of an acid is supplied which makes miniaturization difficult, openings in a fine shape of a resist pattern can be produced. Accordingly, a semiconductor device that has finer shape or impurity distribution than in the related art can be manufactured.

### <3. Example of a Manufacturing Method of a Semiconductor Device>

Hereinafter, the present technology will be described in detail using an example in which resist patterns were actually produced using a second resist composition (chemical shrink material). Note that, in the example provided below, only resist patterns were formed in manufacturing of a semiconductor device and miniaturization of a shape of openings of the formed resist pattern was compared.

### Example 1

### Formation of a First Resist Pattern

First, prior to formation of second resist patterns of the example, a first resist pattern was produced. On the first resist pattern, the second resist patterns for the example and a comparative example were formed for comparison and evaluation.

A resist pattern was formed using P3593 which is a resist for KrF lithography manufactured by Tokyo Ohka Kogyo Co., Ltd., that is a chemical amplifying excimer resist as a first resist composition.

First, the first resist composition was formed on a silicon wafer in a thickness of 1.1 μm using spin coating. Then, a pre-baking process for evaporating a solvent was performed at a temperature of 100° C. for 60 seconds, and thereby a first resist layer was formed. For the formation of the first resist layer, a coater-developer manufactured by SOKUDO Co., Ltd. was used.

Next, using an exposure system manufactured by Canon Inc., exposure was performed by irradiating the formed first resist layer with KrF (krypton fluoride) excimer laser beams having a wavelength of 248 nm in conventional illumination with an NA (numerical aperture) of 0.55 and σ of 0.5.

After the first resist layer was exposed, a PEB process was performed at a temperature of 110° C. for 60 seconds using the coater-developer.

Next, after the first resist layer was developed in paddle development using 2.38 mass % of a TMAH aqueous solution, a heating process was performed at a temperature of 100° C. for 90 seconds. Thereby, a first resist pattern in a line-and-space pattern having a pitch of 1.1 μm was produced. A space width (width of an opening) of the obtained first resist pattern was 0.5 μm and a resist width was 0.6 μm.

(Preparation of a Second Resist Composition)

Next, a second resist composition was prepared.

First, using a measuring flask of 1 L, 100 g of pure water was added to 100 g of a solution having 20 mass % of a polyvinyl acetal resin (S-LEC KW3 and KW1 manufactured by Sekisui Chemical Co., Ltd.), stirred to be mixed for six hours at room temperature, and thereby an aqueous solution having 10 mass % of the polyvinyl acetal resin was obtained.

Further, 860 g of pure water and 40 g of isopropyl alcohol (IPA) were mixed with 100 g of methoxy methylol melamine (Cymel 370 manufactured by Mitsui Cyanamid Ltd.), then the mixture was stirred for six hours at room temperature, and thereby an aqueous solution having about 10 mass % of methoxy methylol melamine was obtained.

Next, 200 g of the prepared aqueous solution having 10 mass % of the polyvinyl acetal resin and 40 g of the aqueous solution having about 10 mass % of methoxy methylol melamine were stirred to be mixed for six hours at room temperature. Accordingly, a mixed aqueous solution having a concentration of methoxy methylol melamine with respect to the polyvinyl acetal resin of 20 mass % was produced.

Next, as an inclusion compound, 0.1 mass % of methyl-β-cyclodextrin (MβCD) was added to the mixed aqueous solution having a concentration of methoxy methylol melamine with respect to the polyvinyl acetal resin of 20 mass % which was prepared according to the method described above, and then the resultant solution was set as the second resist composition (chemical shrink material) of Example 1.

(Formation of a Second Resist Pattern)

The prepared second resist composition of Example 1 was coated on the first resist pattern formed using the chemical amplifying excimer resist using spin coating. The number of rotations in spin coating was 3000 rpm and a duration was 30 seconds. After the spin coating, the solvent (water) was evaporated in a heating process at a temperature of 100° C. for 60 seconds. Next, a mixing baking process was performed at a temperature of 100° C. for two minutes, and then the pattern was washed with water for 30 seconds.

Through the step above, the second resist pattern of Example 1 was formed.

### Comparative Example 1

Excluding the addition of the inclusion compound, another second resist composition (chemical shrink material) was produced using the same method as in Example 1 described above, and thereby another second resist pattern of Comparative Example 1 was formed.

[Result]

For results of Example 1 described above and Comparative Example 1, space widths of openings of resist patterns were measured. FIGS. 3A to 3C show SEM photographs of the first resist pattern after and before the formation of the second resist patterns. For SEM observation of the resist patterns, S3400 that is an SEM manufactured by Hitachi High-Technologies Corporation was used.

FIG. 3A shows a resist pattern of Example 1 after processing using the chemical shrink material. In addition, FIG. 3B shows a resist pattern of Comparative Example 1 after processing using the chemical shrink material to which the inclusion compound is not added. FIG. 3C shows a resist pattern of a reference example before processing using a chemical shrink material. Note that, in FIGS. 3A to 3C, the dark portions indicate resist layers and the bright portions indicate openings of the resist patterns.

In comparison to the first resist pattern shown in FIG. 3C, a result was obtained that the line widths of the resist parts were thickened and the widths of the openings were accordingly narrowed in the resist pattern of Example 1 shown in FIG. 3A and the resist pattern of Comparative Example 1 shown in FIG. 3B.

In addition, with regard to the resist pattern of Example 1 shown in FIG. 3A, a result was obtained that the line widths of the resist parts were remarkably larger and the openings of the resist pattern were finer than those of the resist pattern of Comparative Example 1 shown in FIG. 3B.

The openings of the first resist pattern before the second resist pattern was formed had a space width of 0.50 μm.

On the other hand, the openings of the resist pattern after the second resist pattern of Example 1 was formed had a space width of 0.34 μm. Thus, an amount of shrinkage of the openings toward both sides of the resist pattern caused by the second resist pattern of Example 1 was a total of 160 nm.

In addition, the openings of the resist pattern in which the second resist pattern of Comparative Example 1 was formed had a space width of 0.42 μm. Thus, an amount of shrinkage of the openings toward both sides of the resist pattern caused by the second resist pattern of Comparative Example 1 was a total of 80 nm.

As a result, the second resist pattern of Example 1 could obtain a larger shrinkage amount than that of Comparative Example 1.

Thus, since the second resist composition contains the inclusion compound, the second resist pattern that is sufficiently thick can be formed in comparison to the chemical shrink material of the related art. For this reason, a finer opening shape of a resist pattern than in the related art can be produced.

As described above, by using the chemical shrink material that contains a compound having an inclusion function as a second resist layer, a semiconductor device that has a finer shape or impurity distribution than in the related art can be manufactured.

Note that, in the embodiment described above, although the example in which the second resist pattern is formed on the side walls of the first resist pattern has been described, a portion in which the second resist pattern is formed is not particularly limited. For example, the second resist pattern can also be formed in an upper portion of the first resist pattern.

Note that the present technology is not limited to the configuration described in the embodiment above, and can be variously altered and modified within a scope not departing from a configuration of the present technology.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1) A resist composition including:

a crosslinking material configured to cause crosslinking in the presence of an acid;

an inclusion compound; and

a solvent.

(2) The resist composition according to (1), wherein the inclusion compound is a cyclodextrin derivative.
(3) The resist composition according to (1) or (2), wherein the solvent is water or a mixed solvent of water and a water-soluble organic solvent.
(4) The resist composition according to any one of (1) to (3), wherein the crosslinking material is at least one or more kinds selected from water-soluble crosslinking agents and water-soluble crosslinking resins.
(5) A method for manufacturing a semiconductor device, the method including:

forming, on a semiconductor substrate, a first resist pattern configured to be able to supply an acid using a first resist composition;

forming a second resist layer on the first resist pattern by coating with the resist composition described in any one of (1) to (3);

forming a crosslinked layer in the second resist layer by diffusing the acid from the first resist pattern into the second resist layer; and

removing a non-crosslinked portion of the second resist layer.

(6) The method for manufacturing a semiconductor device according to (5), wherein, in the step of forming a crosslinking structure in the second resist layer, the acid is diffused into the second resist layer by performing heating at a temperature of 70° C. to 150° C.

What is claimed is:

1. A resist composition comprising:
a crosslinking material configured to cause crosslinking in the presence of an acid;
an inclusion compound; and
a solvent.

2. The resist composition according to claim 1, wherein the inclusion compound is a cyclodextrin derivative.

3. The resist composition according to claim 1, wherein the solvent is water or a mixed solvent of water and a water-soluble organic solvent.

4. The resist composition according to claim 1, wherein the crosslinking material is at least one or more kinds selected from water-soluble crosslinking agents and water-soluble crosslinking resins.

5. A method for manufacturing a semiconductor device, the method comprising:
forming, on a semiconductor substrate, a first resist pattern configured to be able to supply an acid using a first resist composition;
forming a second resist layer on the first resist pattern by coating with a second resist composition containing a crosslinking material configured to cause crosslinking in the presence of an acid, an inclusion compound, and a solvent;
forming a crosslinked layer in the second resist layer by diffusing the acid from the first resist pattern into the second resist layer; and
removing a non-crosslinked portion of the second resist layer.

6. The method for manufacturing a semiconductor device according to claim 5, wherein, in the step of forming a crosslinking structure in the second resist layer, the acid is diffused into the second resist layer by performing heating at a temperature of 70° C. to 150° C.
